(19) United States
(12) Patent Application Publication
(10) Pub. No.: US 2025/0040179 A1
(43) Pub. Date: Jan. 30, 2025

(54) SEMICONDUCTOR DEVICE WITH A HIGH K FIELD RELIEF DIELECTRIC STRUCTURE

(71) Applicant: Texas Instruments Incorporated, Dallas, TX (US)

(72) Inventors: Pushpa Mahalingam, Richardson, TX (US); Alexei Sadovnikov, Sunnyvale, CA (US); Nick Dunteman, Draper, UT (US); Ryan Rust, Lehi, UT (US)

(21) Appl. No.: 18/361,880

(22) Filed: Jul. 30, 2023

(51) Int. Cl. H01L 29/78; H01L 29/06; H01L 29/08; H01L 29/423; H01L 29/66

(52) U.S. Cl. CPC H01L 29/7816; H01L 29/0653; H01L 29/0878; H01L 29/4238; H01L 29/66681

(57) ABSTRACT

Semiconductor devices including a high-k field relief dielectric structure are described. The microelectronic device comprises a substrate including a body region and a drain drift region on the substrate, a gate dielectric layer extending over the body region and the drift region, a drain drift trench is formed by removal of silicon dioxide from a LOCOS silicon region, a high-k field relief dielectric structure laterally abutting the gate dielectric layer at a location in the drift region, and a gate electrode on the gate dielectric layer and the field relief dielectric layer. Increasing the dielectric constant of the field relief dielectric structure may improve channel hot carrier performance, improve breakdown voltage, and reduce the specific on resistance. A drain drift trench formed in a trench left after removal of silicon dioxide in a LOCOS region provides improved trench depth uniformity.

### TECHNICAL FIELD

This disclosure relates to the field of microelectronic devices. More particularly, but not exclusively, this disclosure relates to microelectronic devices having a high k dielectric relief dielectric structure.

### BACKGROUND

Semiconductor components are being continually improved to reliably operate with smaller feature sizes. Fabricating semiconductor devices that have increasingly higher performance while meeting reliability specifications is challenging.

### SUMMARY

This summary is provided to introduce a brief selection of disclosed concepts in a simplified form that are further described below in the detailed description including the drawings provided. This summary is not intended to limit the claimed subject matter's scope.

Disclosed examples include a microelectronic device with a high-k field relief dielectric structure. The high-k field relief dielectric structure may include silicon nitride, silicon oxynitride, or other high-k dielectric materials such as Al₂O₃ (k=9.5-12), BaTiO₃ (k=130-1000), lead zirconium titanate (PZT) (k=300-4000), HfO₂ (k=40), Ta₂O₅ (k=27), WO₃ (k=42), and ZrO₂ (k=25). The microelectronic device comprises a substrate including a body region having a first conductivity type and a drift region having a second conductivity type opposite the first conductivity type; a gate dielectric layer on the substrate, the gate dielectric layer extending over an intersection of the body region and the drift region; a high-k field relief dielectric structure on the drift region in a trench formed by Local Oxidation of Silicon (LOCOS) and removal of the locos layer leaving a dielectric trench with local oxidation of silicon profile, the high-k field relief dielectric structure in the dielectric trench abutting the gate dielectric layer at a location in the drift region, and a gate electrode on the gate dielectric layer and the field relief dielectric layer.

The high-k field relief dielectric structure raises the dielectric constant of the field relief dielectric above that of pure silicon dioxide which has a dielectric constant of 3.9. By increasing the dielectric constant of the field relief dielectric structure, channel hot carrier performance may be improved, breakdown resistance may be improved, and specific on resistance of the microelectronic device may be lowered compared to a microelectronic device of similar size with a field relief dielectric structure of silicon dioxide. The microelectronic device also includes a source region disposed in the body region, the source region having the second conductivity type; and a drain region disposed in the drift region, the drain region having the second conductivity type.

### BRIEF DESCRIPTION OF THE VIEWS OF THE DRAWINGS

FIG. 1A through FIG. 1P are cross sections of an example microelectronic device including a transistor with a high-k field relief dielectric structure in various stages of formation.

FIG. 2 is a top-down view of an example microelectronic device including a transistor with a high-k field relief dielectric structure.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure is illustrated by embodiments directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to presently preferred embodiments.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” as used herein, may refer to ±5% to ±10% variations of the recited values in some cases. In other cases, the term “approximately” may refer to ±10% to ±20% variations of the recited values.

Microelectronic devices are being continually improved to reliably operate with smaller feature sizes. Fabricating such microelectronic devices satisfying area scaling and reliability requirements is challenging. A metal-oxide-semiconductor (MOS) transistor may include features for supporting high voltage operations—e.g., with a voltage applied to their drain (or drain structure) of about 20V, 30V, 40V, or even greater. Such MOS transistors may include drain diffusion profiles (or drain junction profiles) devised to support the high voltages applied to the drain—e.g., having an extended portion to distribute the voltage drop across wider areas. Accordingly, such MOS transistors may be referred to as drain-extended MOS transistors, for example drain-extended n-channel MOS (DENMOS) transistors, drain-extended p-channel MOS (DEPMOS) transistors, laterally-diffused MOS (LDMOS) transistors, as well as groups of DENMOS and DEPMOS transistors (which may be referred to as complimentary drain-extended MOS or DECMOS transistors). Other devices such as a gated bipolar semiconductor device, a gated unipolar semiconductor device, an insulated gate bipolar transistor (IGBT), a metal oxide semiconductor (MOS)-triggered SCR, a MOS-controlled thyristor, and a gated diode, are also within the scope of the disclosure.

Disclosed examples include a microelectronic device with a high-k field relief dielectric structure. As used herein, the term high-k dielectric refers to a dielectric material having a dielectric constant greater than silicon dioxide. In one embodiment, the high-k dielectric is silicon nitride, Si₃N₄, which has a dielectric of 7.9. Silicon oxide has a dielectric constant of 5 and silicon dioxide has a dielectric constant of 3.9. Other high-k dielectric materials which may be used for a high-k field relief dielectric layer may include Al₂O₃ (k=9.5-12), BaTiO₃ (k=130-1000), lead zirconium titanate (PZT) (k=300-4000), HfO₂ (k=40), Ta₂O₅ (k=27), WO₃ (k=42), hafnium dioxide, hafnium silicate, zirconium silicate and ZrO₂ (k=25). Other high-k dielectric materials are within the scope of this disclosure. The high-k field relief dielectric structure contains a field relief dielectric material with a dielectric constant higher than silicon dioxide. The microelectronic device comprises a substrate including a body region having a first conductivity type and a drift region having a second conductivity type opposite the first conductivity type; a gate dielectric layer on the substrate, the gate dielectric layer extending over an intersection of the body region and the drift region; a high-k field relief dielectric structure on the drift region in a recessed LOCOS formed trench, the high-k field relief dielectric structure laterally abutting the gate dielectric layer at a location in the drift region, and a gate electrode on the gate dielectric layer and the high-k field relief dielectric structure.

The increase in permittivity and dielectric constant by introducing a high-k material as the field relief dielectric structure both distributes the electric field more uniformly across the field relief dielectric structure and reduces the peak electric field near the junction of the gate dielectric and the field relief dielectric structure. This reduction of the maximum electric field and more uniform distribution of the electric field results in greater surface breakdown voltage for a high-k field relief dielectric structure in an LDMOS microelectronic device and other drain extended microelectronic devices compared to a similar device with a silicon dioxide field relief dielectric structure. The improvement in surface breakdown voltage with a high-k field relief dielectric structure also enables increased doping of the body region which improves body breakdown voltage while simultaneously reducing the on-resistance of the LDMOS microelectronic device with a high-k field relief dielectric structure. An added benefit of the higher dielectric constant of the high-k field relief dielectric structure is improved channel hot carrier (CHC) performance compared to a silicon dioxide relief dielectric structure in a given device. The microelectronic device also includes a source region disposed in the body region, the source region having the second conductivity type; and a drain region disposed in the drift region, the drain region having the second conductivity type.

Described examples include doped regions of various semiconductor structures which may be characterized as p-doped and/or n-doped regions or portions, and include regions that have majority dopants of a particular type, such as n-type dopants (providing electrons as charge carriers) or p-type dopants (providing holes as charge carriers). For the purposes of this description, doping of the first conductivity type may be n-type doping, and doping of the second conductivity type may be p-type doping.

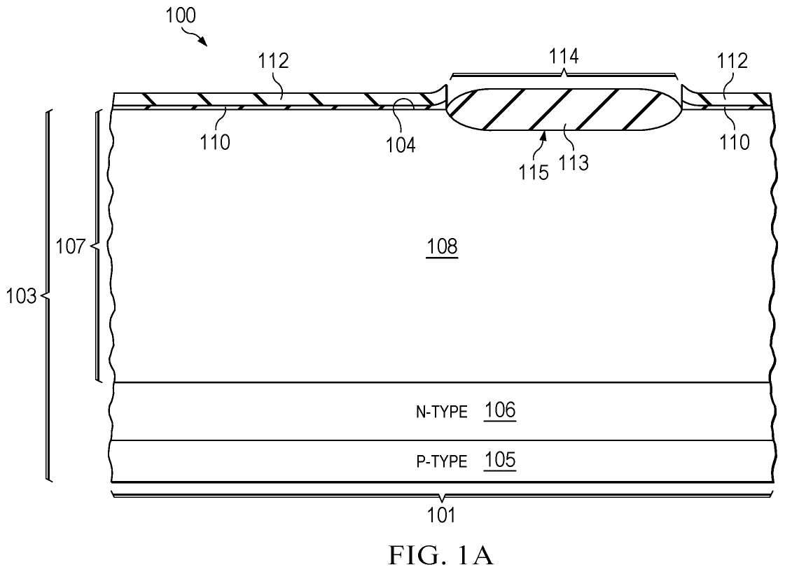

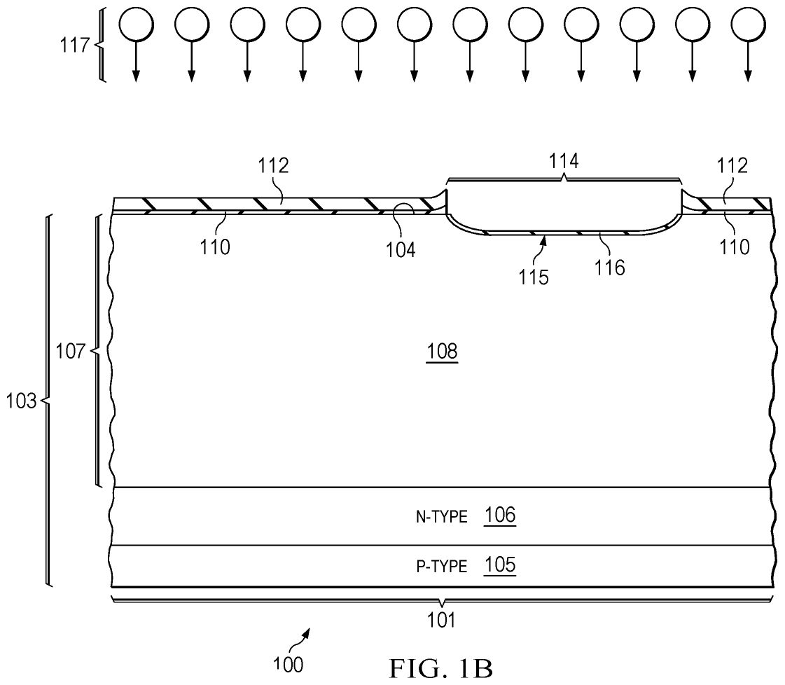

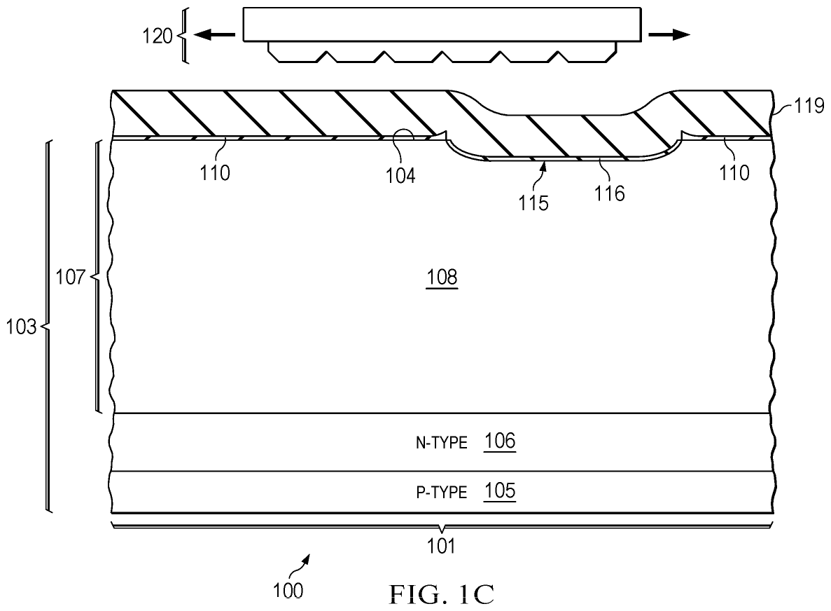

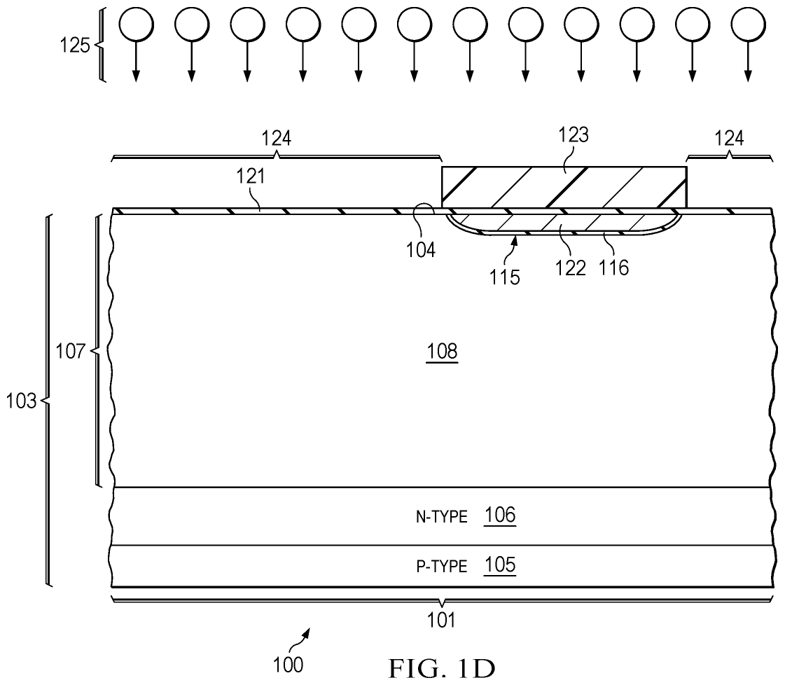

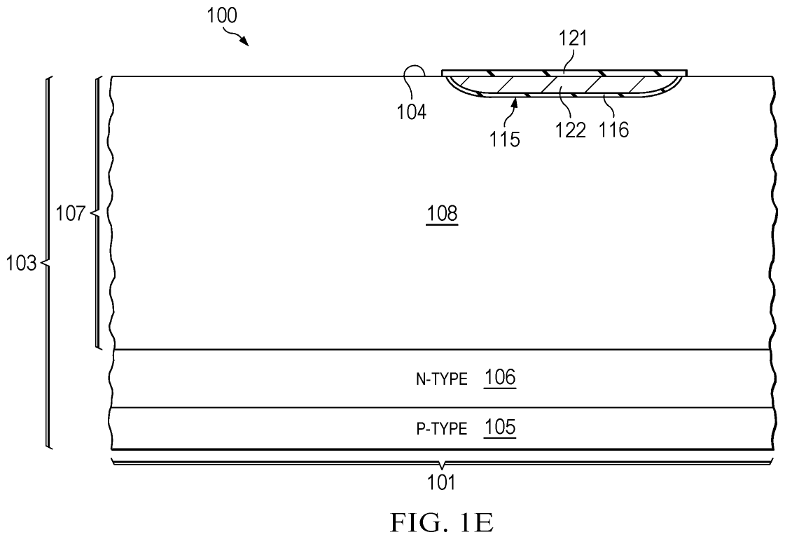

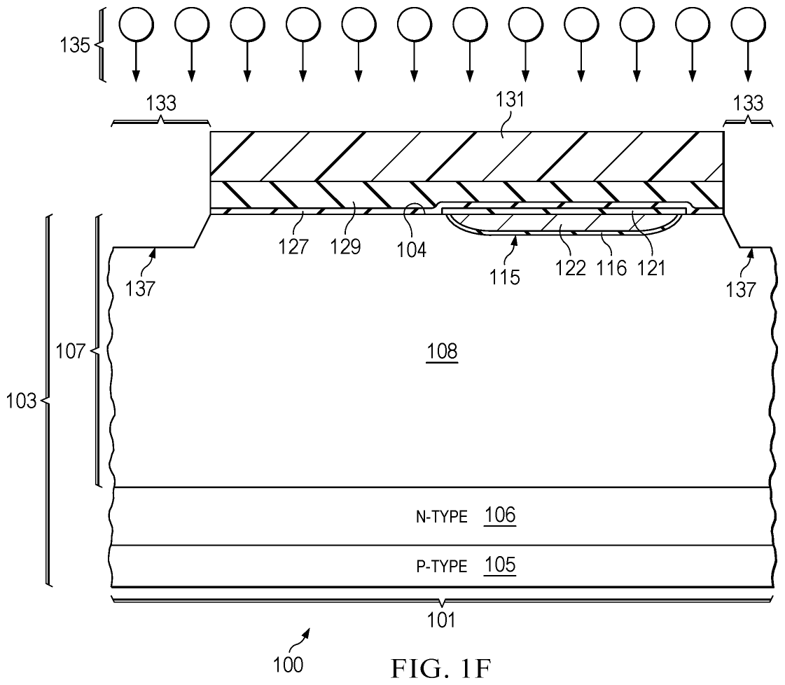

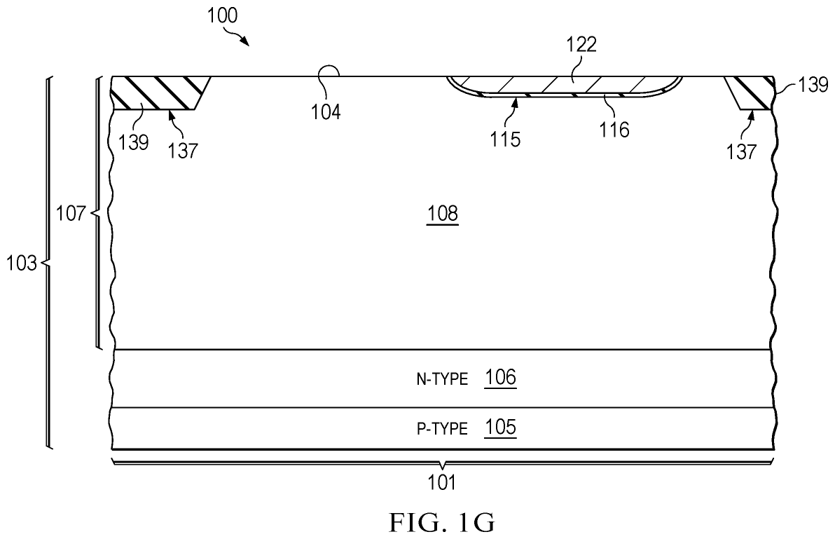

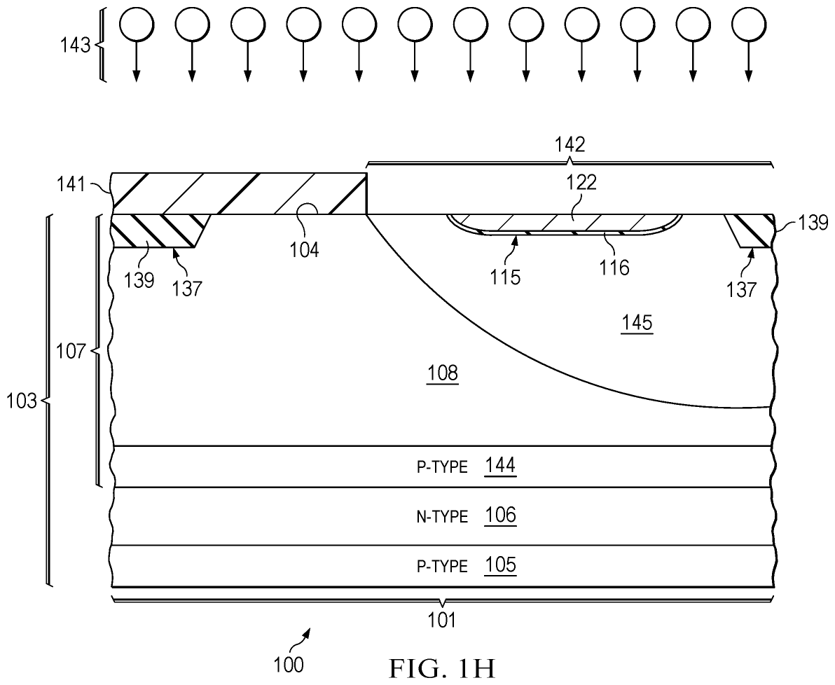

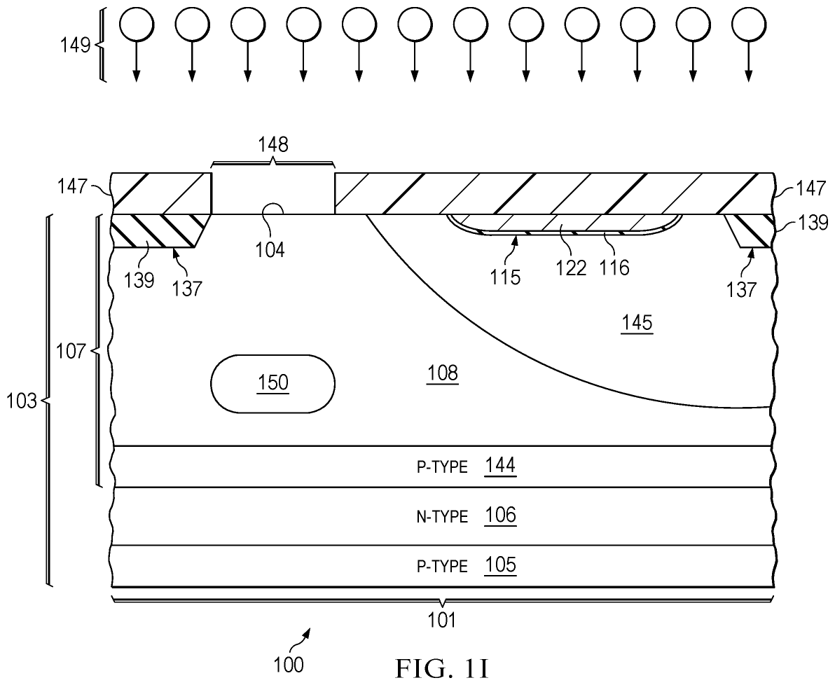

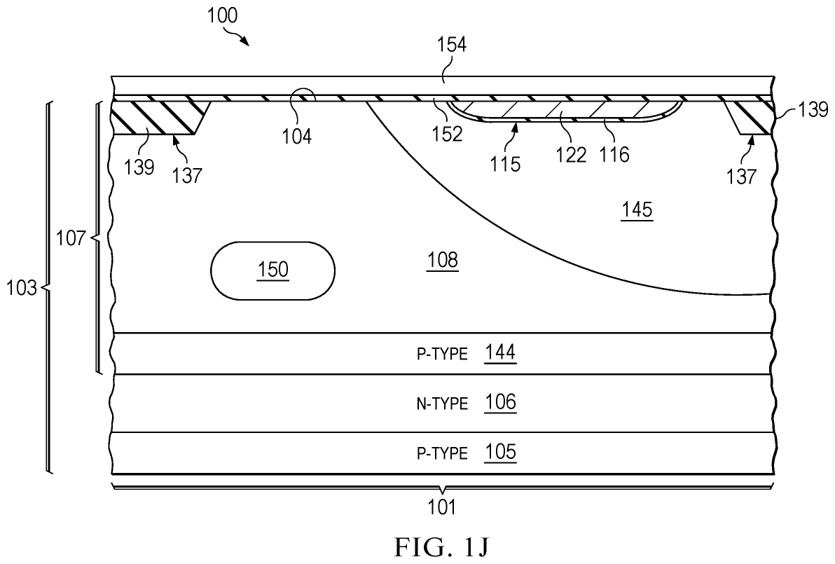

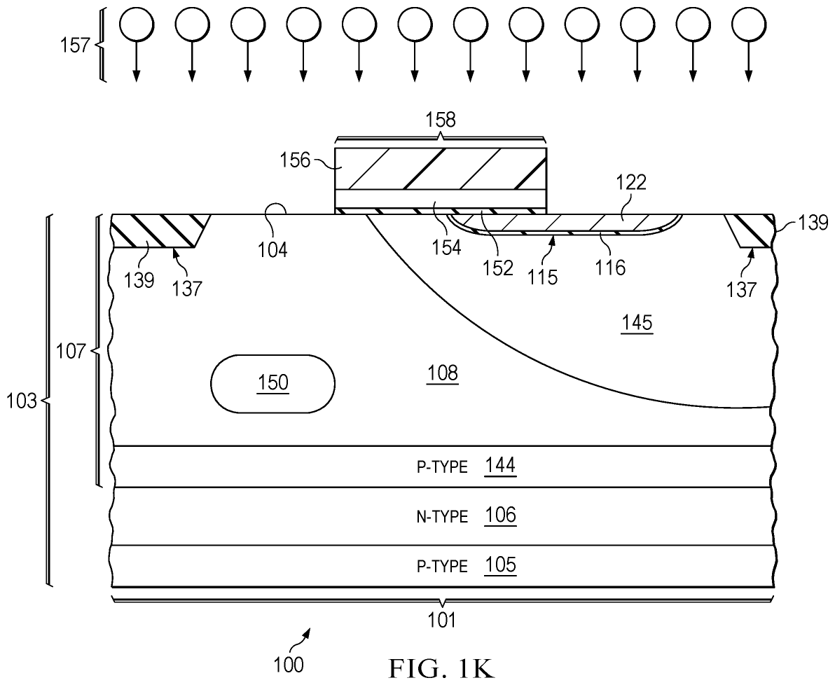

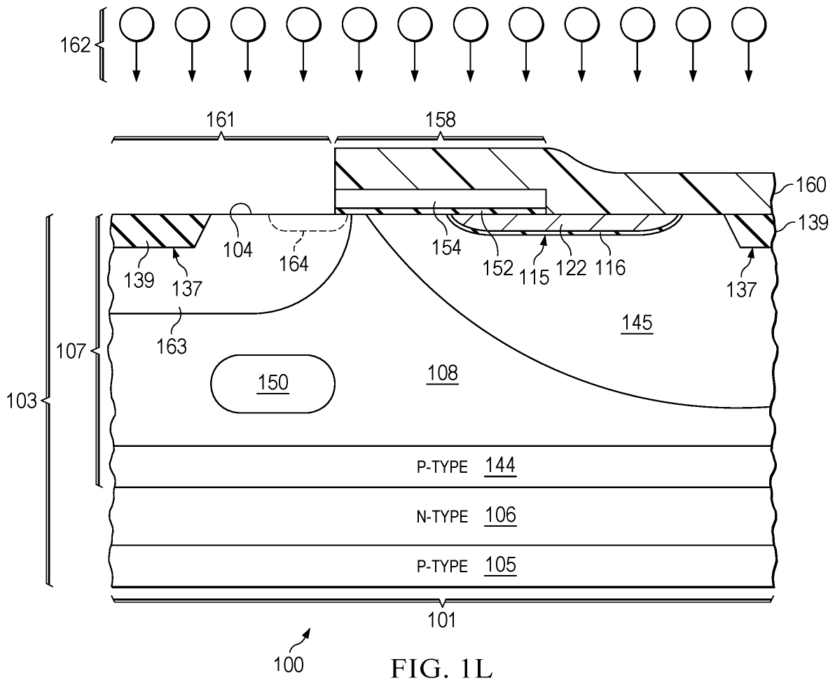

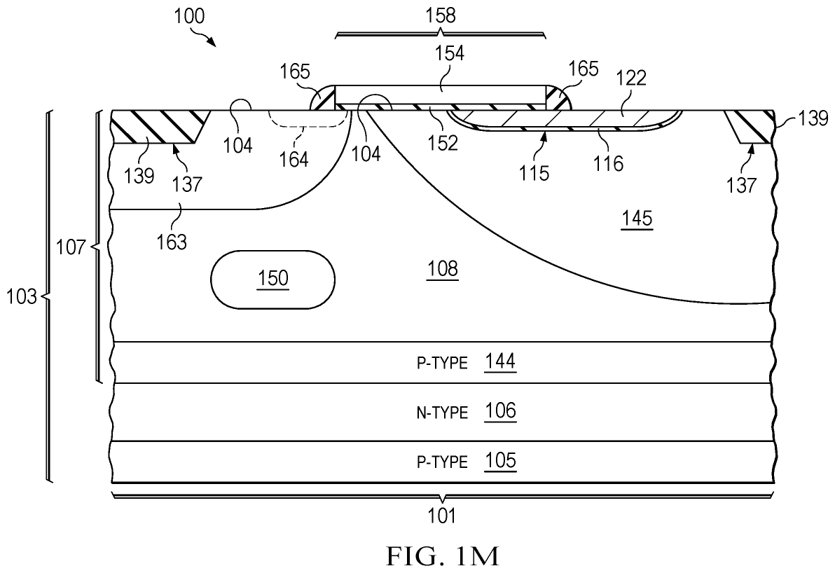

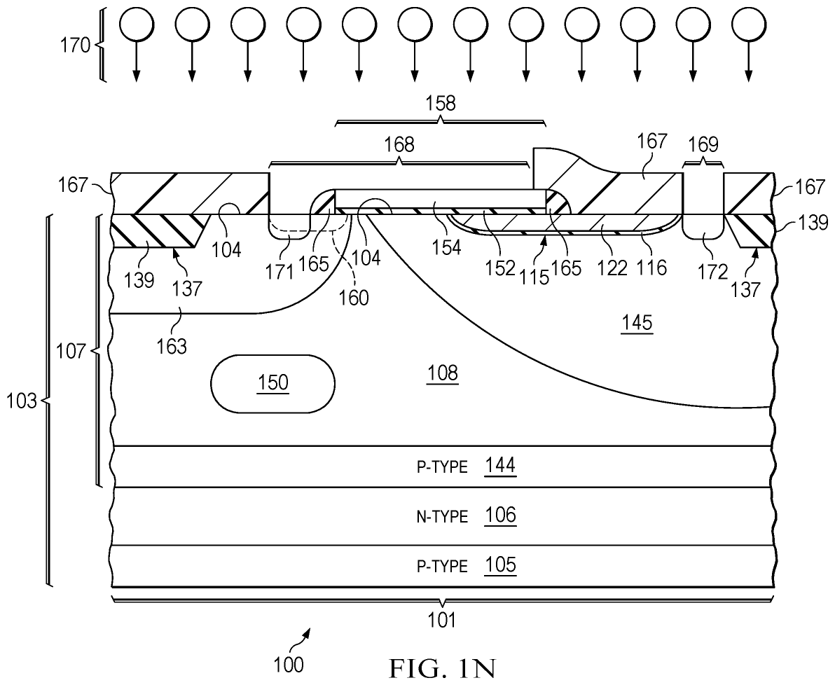

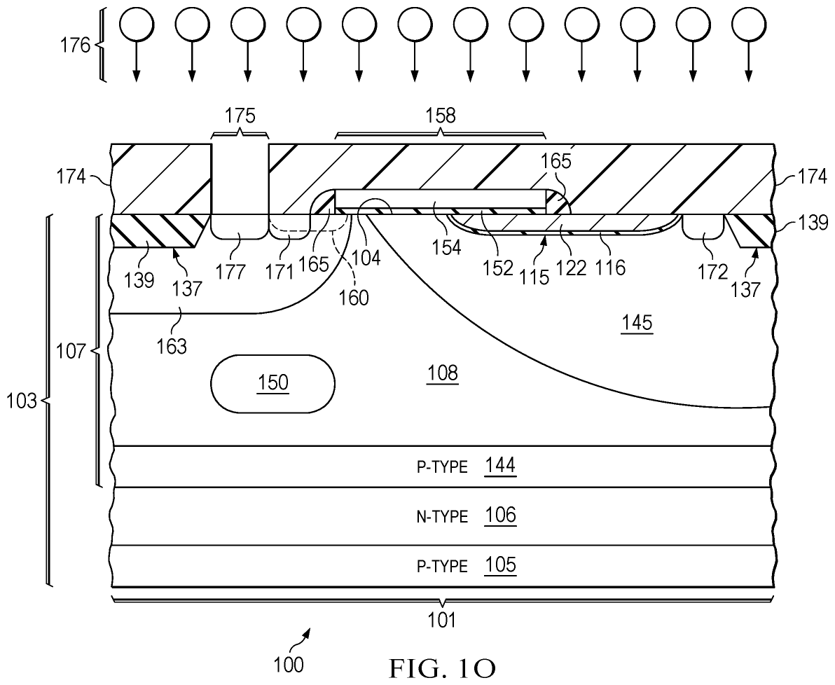

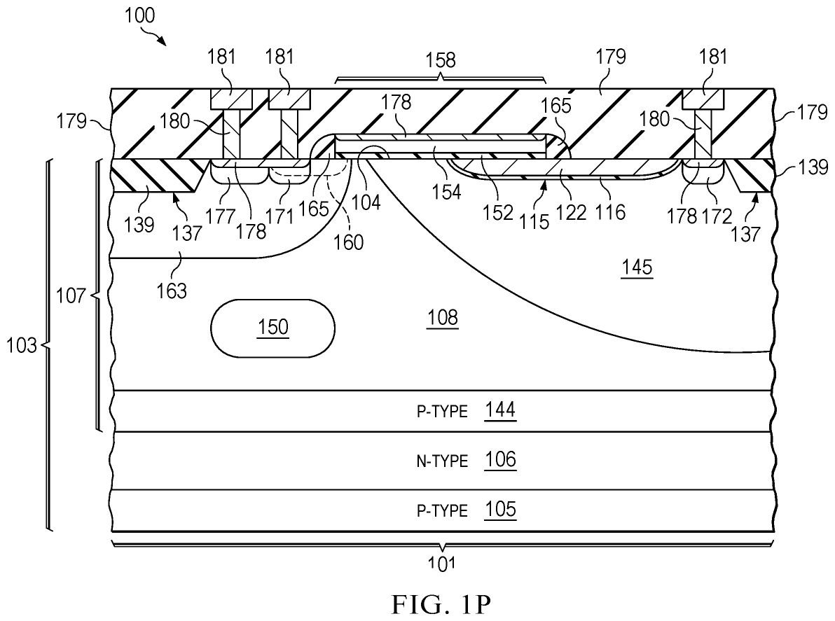

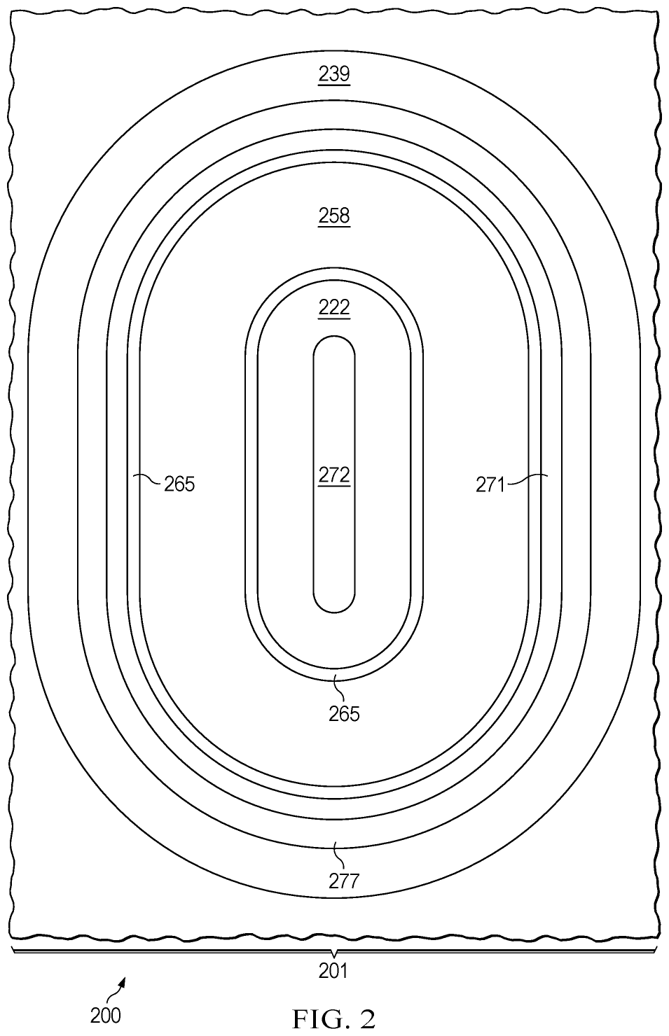

FIG. 1A through FIG. 1P are cross sections of an example microelectronic device 100 including a LDMOS transistor 101 in successive stages of an example method of formation. The LDMOS transistor 101 may have a racetrack layout (gate electrode with a closed-loop configuration) as described with reference to FIG. 2. Although the LDMOS transistor 101 described herein is an n-channel type (or an n-channel LDMOS), a p-channel type LDMOS transistor (or a p-channel LDMOS) can be formed in accordance with the present disclosure when n-doped regions are substituted by p-doped regions, and p-doped regions are substituted by n-doped regions.

FIG. 1A shows a cross section of a microelectronic device 100 which includes a base wafer 105 consisting of a semiconductor material, referred to herein as the substrate 103. The substrate 103 has a top surface 104. The base wafer 105 may be, for example, part of a bulk semiconductor wafer, part of a semiconductor wafer with an epitaxial layer, part of a silicon-on-insulator (SOI) wafer, or other structure suitable for forming the microelectronic device 100.

The base wafer 105 may include an optional n-type buried layer (NBL) 106 on the base wafer 105. The base wafer 105 may be p-type with a dopant concentration of 1×10¹⁷ atoms/cm³ to 1×10¹⁸ atoms/cm³, for example. Alternatively, the base wafer 105 may be lightly doped, with an average dopant concentration below 1×10¹⁶ atoms/cm³. The NBL 106 may be 2 microns to 10 microns thick, by way of example, and may have a dopant concentration of 1×10¹⁷ atoms/cm³ to 1×10¹⁸ atoms/cm³. The substrate 103 may include an epitaxial layer 107 of silicon on the NBL 106. The epitaxial layer 107 is part of the substrate 103, and may be 2 microns to 12 microns thick, for example. The epitaxial layer 107 may be p-type, with a dopant concentration of 1×10¹⁵ atoms/cm³ to 1×10¹⁶ atoms/cm³, by way of example. In versions of this example in which the base wafer 105 lacks the NBL 106, the epitaxial layer 107 may be directly on the base wafer 105. As will become apparent in the discussion the epitaxial layer 107 may serve as a body region 108 of the LDMOS transistor 101. The body region 108 has a first conductivity type.

A first pad oxide layer 110 of silicon dioxide may be formed on the substrate 103. The first pad oxide layer 110 may include silicon dioxide that is formed by a thermal oxidation process or a chemical vapor deposition (CVD) process. The first pad oxide layer 110 may provide stress relief between the substrate 103 and subsequent layers. The first pad oxide layer 110 may be 5 nm to 50 nm thick, by way of example. A first silicon nitride layer 112 may then deposited and a photomask formed (not specifically shown). The photomask serves the function of masking the first silicon nitride layer 112 and first pad oxide layer 110 and it may include a light sensitive organic material that is coated, exposed, and developed. The photomask leaves the first silicon nitride layer 112 and the first pad oxide layer 110 exposed in a stress relief opening region 114. A plasma etch process (not specifically shown) removes the first silicon nitride layer 112 and the first pad oxide layer 110 in the stress relief opening region 114 where a high-k field relief dielectric layer 119 (as shown in FIG. 1C) will eventually be formed. After the removal of the first silicon nitride layer 112 and the first pad oxide layer 110 in the stress relief opening region 114, a silicon dioxide layer 113 may be formed by a local oxidation of silicon (LOCOS) process in the stress relief opening region 114 where the top surface 104 of the substrate 103 is exposed. In the LOCOS process the substrate 103 is heated to an elevated temperature in the presence of oxygen and a chemical reaction occurs between available oxygen and the top surface 104 of the substrate. The chemical reaction consumes silicon in the substrate 103 as the formation of the silicon dioxide layer 113 progresses. A portion of the resulting silicon dioxide layer 113 is below the top surface 104 of the substrate 103. The silicon dioxide layer 113 may have a thickness in a range between 50 nm and 150 nm. The silicon dioxide layer 113 may have a tapered edge along a perimeter where the silicon dioxide layer 113 meets the top surface 104 of the substrate 103. The tapered edge of the silicon dioxide layer 113 may be referred to as a “bird's beak” region. The interface between the bottom surface of the silicon dioxide layer 113 and the substrate 103 in the stress relief opening region 114 forms a field relief trench 115 as referred to in FIG. 1B, FIG. 1C, and FIG. 1D

Referring to FIG. 1B, a plasma etch process 117 may be used to remove the silicon dioxide layer 113 and expose the substrate 103 in the field relief trench 115. A wet etch process (not specifically shown) may also be used after the plasma etch process 117 to expose the substrate in the field relief trench 115. The surface of the field relief trench 115 has a recessed local oxidation of silicon profile. It is advantageous to form the field relief trench 115 defined by a silicon dioxide layer 113 derived through a LOCOS process, as LOCOS oxidation of silicon is a very well controlled process which results in a field relief trench 115 which advantageously may be made with very high depth and profile uniformity, and high predictability both within wafer and wafer to wafer compared to other methods. The high depth and profile uniformity within wafer and wafer to wafer advantageously results in more uniform electrical performance of the resulting LDMOS transistor 101.

A thermal oxidation of the substrate 103 (not specifically shown) in the field relief trench 115 forms a field relief dielectric liner 116 of silicon dioxide. An in-situ steam generation (ISSG) oxide may also be used to form the field relief dielectric liner 116. Other dielectric materials and method of formation of the field relief dielectric liner 116 are within the scope of the disclosure. The field relief dielectric liner 116 may be 3 nm to 20 nm by way of example. Following the deposition of the field relief dielectric liner 116 the first silicon nitride layer 112 may be removed using a phosphoric acid based wet chemical process which leaves the field relief dielectric liner 116 and the first pad oxide layer 110 on the top surface 104.

Referring to FIG. 1C, a high-k field relief dielectric layer 119 is deposited on the first pad oxide layer 110 and the field relief dielectric liner 116 in the field relief trench 115. While the high-k field relief dielectric layer 119 in the example embodiment is silicon nitride, other high-k dielectric materials such as Al₂O₃, BaTiO₃, PZT, HfO₂. Ta₂O₅, WO₃, and ZrO₂ may be used. Additional high-k materials are within the scope of the disclosure. The thickness of the high-k field relief dielectric layer 119 may be 90 nm to 300 nm by way of example. A Chemical Mechanical Planarization (CMP) 120 process is used to remove the overburden of the high-k field relief dielectric layer 119 in areas outside of the field relief trench 115. The CMP 120 process stops on or in the first pad oxide layer 110. It is advantageous for the CMP 120 process to stop on or in the first pad oxide layer 110 to achieve uniform thickness of the high-k field relief dielectric layer 119 remaining in the field relief trench 115 both across a silicon wafer and between wafers. Additionally, it is advantageous to stop the CMP 120 process on or in the first pad oxide layer 110 to minimize local topography which may limit the depth of focus (DOF) of subsequent lithographic operations. After the CMP 120 process, the wafer is cleaned and the remaining first pad oxide layer 110 is removed in a wet chemical step (not specifically shown).

Referring to FIG. 1D, a field relief dielectric cap 121 may be deposited on the top surface 104. The field relief dielectric cap 121 may be of silicon dioxide deposited by a PECVD or CVD process. Other dielectric materials are within the scope of the disclosure. The thickness of the field relief dielectric cap 121 may be 10 nm to 50 nm by way of example.

After the deposition of the field relief dielectric cap 121 a high-k stress relief layer cap resist 123 is patterned and exposed leaving the high-k stress relief layer cap resist 123 over the high-k field relief dielectric structure 122, with a field relief dielectric cap resist space 124 over the remaining regions of the LDMOS transistor 101. A plasma etch process 125 is used to remove the field relief dielectric cap 121 in the field relief dielectric cap resist space 124 while leaving the field relief dielectric cap 121 under the field relief dielectric cap resist 123. As shown in FIG. 1E, the remaining field relief dielectric cap 121 after the etch process covers the high-k field relief dielectric structure 122. After the plasma etch process 125 the resist is removed and the wafer may be cleaned (not specifically shown).

FIG. 1F shows a cross section after a Shallow Trench Isolation (STI) plasma etch 135 forms an STI trench 137. The STI formation begins with the formation of a second pad oxide layer 127 on the top surface 104. The second pad oxide layer 127 may provide stress relief between the substrate 103 and subsequent layers. The second pad oxide layer 127 may be 5 nm to 50 nm thick, by way of example. A STI nitride layer 129 is formed on the second pad oxide layer 127. The STI nitride layer 129 may be 50 nm to 150 nm by way of example. The STI nitride provides a CMP stopping layer for a subsequent CMP process as discussed in FIG. 1G. After the formation of the second pad oxide layer 127 and the STI nitride layer 129, a STI pattern 131 is formed on the STI nitride layer 129 and exposed with STI resist open areas 133. The STI plasma etch 135 forms the STI trench 137. After the formation of the STI trench 137, the STI pattern 131 is removed and the top surface 104 may be cleaned.

FIG. 1G shows a cross section after the formation of the STI dielectric region 139. The STI dielectric region 139 is a field oxide surrounding the LDMOS transistor 101 providing isolation for the LDMOS transistor 101. After the STI trench 137 has been formed, and following the removal of the STI pattern 131 and cleaning of the top surface 104 as discussed in FIG. 1F, a STI dielectric layer (not specifically shown) is formed in the STI trench 137 and on the top surface 104. The STI dielectric layer may be a dielectric such as silicon dioxide which is deposited by a high-density plasma (HDP) or an atmospheric pressure chemical vapor deposition (APCVD). Other deposition methods are within the scope of the disclosure. The STI dielectric layer may be 150 nm to 500 nm by way of example. After the STI dielectric is formed, a CMP process (not specifically shown) is used to remove the overburden of the STI dielectric layer, stopping on the STI nitride and defining the STI dielectric region 139. A first wet etch using a phosphoric acid chemistry is used to remove the STI nitride layer 129 referred to in FIG. 1F, and a HF based chemistry is used to remove the second pad oxide layer 127 and the field relief dielectric cap 121. The second pad oxide layer 127 and the field relief dielectric cap 121 protect the high-k field relief dielectric structure 122 from the phosphoric acid wet etch chemistry used to remove the STI nitride layer 129.

FIG. 1H shows a cross section after a n-drift resist 141 is deposited and patterned to form an n-drift resist opening 142. One or more n-type implants 143 are performed to form a drain drift region 145 (which may be referred to as an n-drift region) in the exposed areas of the substrate 103. The n-type implants 143 to define the drain drift region 145 may occur in multiple steps. For example, phosphorus may be implanted at a total dose of between 1×10¹² cm⁻² and 1×10¹³ cm⁻² with energies suitable for forming the drain drift region 145 with or without subsequent thermal cycles. Arsenic may also be implanted with a similar dose with an energy relatively less than the phosphorus implant. After the n-type implants 143, the n-drift resist 141 is removed.

Also referring to FIG. 1H, an optional p-type buried layer (PBL) 144 may formed using a high energy p-type implant (not specifically shown) to add p-type doping to the epitaxial layer 107. The high energy p-type implant can comprise boron at a dose from 1×10¹² cm⁻² to 1×10¹³ cm⁻² at an energy of 400 keV to 3 mega-electron volts (MeV). Indium may also be used as the implant species. For low voltage (e.g., 20 V) versions of the LDMOS transistor 101, the high energy p-type implant can be a blanket implant, while for higher voltage (e.g., >30 V) versions of the LDMOS transistor 101, the high energy p-type implant may be a masked implant to allow selective placement. For the masked implant, a photomask (not specifically shown) is deposited and patterned with an opening which exposes regions of the epitaxial layer 107 where the high energy p-type implant is to be implanted. The high energy p-type implant is followed by a thermal drive (not specifically shown) which extends the high energy p-type implant species below the drain drift region 145. The dedicated thermal drive is optional as the activation of the high energy p-type implant species may also be done during the same damage anneal as used after a n-type dwell region 164 formation discussed in FIG. 1M and after a p-type shallow well region 150 formation discussed in FIG. 1I.

Referring to FIG. 1I, a shallow p-type well photomask 147 is deposited and patterned with a p-type shallow well opening 148 which exposes regions for a shallow p-type well implant 149 in the substrate 103 which forms the p-type shallow well region 150. The p-type shallow well implant 149 may comprise one or more implant steps, each at different energies. Body region doping provided by the p-type shallow well region 150 increases the base doping level to suppress parasitic bipolar transistor formation within the LDMOS transistor 101 and increase safe operating area (SOA). After the shallow p-well implant 149, the shallow p-type well photomask 147 is removed and the wafer cleaned.

Referring to FIG. 1J a cross section is shown after the formation of a gate dielectric layer 152 and a gate polysilicon layer 154. The gate dielectric layer 152 may be formed in a high temperature furnace operation or a rapid thermal process. Other methods of forming the gate dielectric layer 152 are within the scope of this disclosure. The thickness of the gate dielectric layer 152 may range from approximately 3 nm to 15 nm for silicon dioxide or a silicon oxynitride (SiON) gate dielectric which may be slightly thinner but with a higher dielectric constant than that of silicon dioxide, which is about 3.9, by way of example. The gate polysilicon layer 154 is formed on the gate dielectric layer 152. In some examples, the gate polysilicon layer 154 is formed by a deposition process using one or more silane-based precursors to deposit polycrystalline silicon (which may be referred to as polysilicon). In other examples, a replacement gate process may be used to form the gate polysilicon layer 154. The gate polysilicon layer 154 in this example includes polycrystalline silicon. The gate polysilicon layer 154 has a thickness that may range from approximately 50 nm to 300 nm. Moreover, the gate polysilicon layer 154 may be undoped as-deposited. Subsequently, the gate polysilicon layer 154 will be doped as described in more detail with reference to FIG. 1N.

FIG. 1K shows a cross section after a gate resist 156 has been formed and after a gate plasma etch 157. The gate plasma etch 157 removes previously formed gate dielectric layer 152 and the gate polysilicon layer 154 in areas not covered by the gate resist 156 with the area under the gate resist 156 defining a gate electrode 158. The gate electrode 158 may have a racetrack layout (closed-loop configuration) as described with reference to FIG. 2. After the gate plasma etch 157 is complete, the gate resist 156 is removed and a wet or dry process may be used to clean the wafer surface. The gate electrode 158 extends over part of the body region 108, part of the drain drift region 145, and part of the high-k field relief dielectric structure 122 of the LDMOS transistor 101. One end of the gate electrode 158 terminates over the high-k field relief dielectric structure 122 while the opposite end of the gate electrode 158 terminates over the subsequently formed p-type well region 163 (referred to in FIG. 1L)—e.g., over the p-type well region 163 in the body region 108, which is electrically connected to the source region 171 that is formed later as depicted in FIG. 1N.

FIG. 1L shows a cross section after a p-type well resist 160 is deposited and patterned to form a p-type well resist opening 161. FIG. 1J also shows that a p-type implant 162 is performed to form a p-type well region 163 (which may be referred to as a p-well region). The p-type dopants implanted by the p-type implant 162 may include boron and/or indium. For example, a series of boron implants with an energy between 80 keV and 3 MeV, and doses between 4.0×10¹² cm⁻² to 1.5×10¹⁴ cm⁻², with a tilt angle of less than 10 degrees may be used to implant the p-type well region 163. The p-type well region 163 and the body region 108 form the body of the LDMOS transistor 101. After the p-type implant 162, the p-type well resist 160 is removed. Subsequently, a thermal process may be used to activate dopants—e.g., dopants in the drain drift region 145 and dopants in the p-type well region 163. Optionally, an n-type dopant such as arsenic or antimony can also be added to a source side of the LDMOS transistor 101 (resist pattern not shown) to form an n-type dwell region 164. For example, arsenic with a dose 5×10¹³ cm⁻² to 1.2×10¹⁵ cm⁻² (e.g., 8×10¹⁴ cm⁻²) an energy 10 keV to 50 keV (e.g., 15 kcV and a 15 degree ion implant tilt angle) may be used in one particular example for the n-type dwell region 164 dopant, or some or all of this implant angled for example 45 degrees (2 or 4 rotations). The implant angle can also be straight as well (at 0 degrees) or from zero to 45 degrees.

Referring to FIG. 1M, a sidewall 165 may be formed on the lateral surfaces of the gate electrode 158. The sidewall 165 is formed by a blanket formation with one or more conformal layers of a dielectric material over the substrate 103 and over the gate electrode 158. The dielectric material is subsequently removed from horizontal surfaces, that is, surfaces generally parallel to the top surface 104 of the substrate 103, by an anisotropic etch process such as a reactive-ion etching (RIE) process, leaving the dielectric material on the lateral surfaces of the gate electrode 158 as the sidewall 165. The sidewall 165 may include dielectric materials such as silicon dioxide, silicon nitride, or both. The sidewall 165 may extend 50 nanometers to 200 nanometers from the lateral edge of the gate electrode 158.

FIG. 1N shows a cross section after a source and drain resist 167 is deposited and patterned. A source and drain implant 170 implants n-type dopants through a source and gate opening 168 into the substrate 103 to implant the gate electrode 158 and the source region 171. The source and drain implant 170 concurrently implants n-type dopants into the substrate 103 to form the drain region 172 through a drain resist opening 169. The source and drain implant 170 may occur in one or more steps with implant species including one or more of phosphorus and arsenic with an overall dose of between 5×10¹³ cm⁻² and 4.5×10¹⁵ cm⁻² and an energy between 2 keV and 80 keV. The source region 171 and drain region 172 contain an average dopant density at least twice that of the drain drift region 145. After the formation of the source region 171 and the drain region 172, the source and drain resist 167 is removed.

Referring to FIG. 1O, a second source and drain resist 174 is deposited and patterned to form a second source and drain resist opening 175 for a subsequent second source and drain implant 176. The second source and drain implant 176 implants p-type dopants to form the back gate region 177 of the LDMOS transistor 101. The second source and drain implant 176 also implants p-type dopants for source and drain areas in p-type channel transistors in the microelectronic device 100 (not specifically shown). The second source and drain implant 176 may occur in one or more steps with implant species including boron (or indium) with an overall dose and energy suitable to provide degenerate doping to the back gate region 177—e.g. an active average dopant density greater than 1×10¹⁹/cm³ near the solubility limit of the dopant atoms in the back gate region 177. After the second source and drain implant 176, the second source/drain resist 174 is removed.

FIG. 1P shows a cross section of the LDMOS transistor 101 after a first level of interconnects 181 are complete. In some examples, a metal silicide layer 178 may be formed on exposed areas of the top surface 104 of the substrate 103 and the top surface of the gate electrode 158. The metal silicide layer 178 provides lower contact resistance than a similar microelectronic device without a metal silicide layer 178. The metal silicide layer 178 may be formed by forming a layer of metal on the microelectronic device 100 at the top surface 104, contacting the substrate 103 and contacting the gate electrode 158. The layer of metal may include platinum, tungsten, titanium, cobalt, nickel, chromium, or molybdenum, by way of example. A cap layer of titanium nitride or tantalum nitride may be formed over the layer of metal (not specifically shown). Subsequently, the microelectronic device 100 is heated to react the layer of metal with the substrate 103, and the polysilicon of the gate electrode 158 to form the metal silicide layer 178. Unreacted metal is removed from the microelectronic device 100, leaving the metal silicide layer 178 in place. The unreacted metal may be removed by a wet etch process using an aqueous mixture of sulfuric acid and hydrogen peroxide, or an aqueous mixture of nitric acid and hydrochloric acid, by way of example.

For the LDMOS transistor 101, the metal silicide layer 178 is used to provide an electrical connection between the source region 171 and the back gate region 177. A pre-metal dielectric (PMD) layer 179 is formed over the top surface 104 of the substrate 103. The PMD layer 179 may include one or more dielectric layers, such as silicon nitride, silicon oxynitride, silicon dioxide, or the like. In some examples, the PMD layer 179 includes a PMD liner (not specifically shown) and a main dielectric sublayer formed on the PMD liner. Subsequently, the PMD layer 179 may be planarized by a chemical mechanical polish (CMP) process (not specifically shown).

Contacts 180 through the PMD layer 179 may be formed. The contacts 180 may be formed by patterning and etching holes through the PMD layer 179. Contacts 180 may be filled by sputtering titanium to form a titanium adhesion layer, followed by forming a titanium nitride diffusion barrier. A tungsten core may then be formed by a process using tungsten hexafluoride (WF₆). The tungsten, titanium nitride, and titanium are subsequently removed from a top surface of the PMD layer 179 by a plasma etch process, a tungsten CMP process, or a combination of both, leaving the contacts 180 extending to the top surface of the PMD layer 179.

Interconnects 181 may be formed on the contacts 180. The contacts 180 and interconnects 181 provide electrical contact between the LDMOS transistor 101 and other components of the microelectronic device 100. In the cross section shown in FIG. 1P, the electrical connection to the gate electrode 158 is out of the plane of the cross section In versions of this example in which the interconnects 181 have an etched aluminum structure, the interconnects 181 may be formed by depositing an adhesion layer, an aluminum layer, and an anti-reflection layer, and forming an etch mask (not explicitly shown) followed by an RIE process to etch the anti-reflection layer, the aluminum layer, and the adhesion layer where exposed by the etch mask, and subsequently removing the etch mask.

In versions of this example in which the interconnects 181 have a damascene structure, the interconnects 181 may be formed by forming an inter-metal dielectric (IMD) layer (not specifically shown) on the PMD layer 179, and etching interconnect trenches through the IMD layer to expose the contacts 180. The interconnect trenches may be filled with a barrier liner and copper. The copper and barrier liner may be subsequently removed from a top surface of the IMD layer by a copper CMP process.

FIG. 2 is a top-down view of a microelectronic device 200 including a LDMOS transistor 201 in a racetrack configuration—e.g., a racetrack layout generally having dimensions greater in a first orientation than in a second orientation perpendicular to the first orientation (or generally rectangular layouts with rounded corners). The racetrack configuration may also be referred to as a closed-loop configuration. The LDMOS transistor 201 includes aspects of the LDMOS transistor 101 described with reference to FIG. 1A through FIG. 1P. The LDMOS transistor 201 includes a gate electrode 258 in a racetrack configuration.

As shown in FIG. 2, the drain region 272 may be singular innermost element of the LDMOS transistor 201. The other layers visible of the LDMOS transistor 201 in the top-down view of FIG. 2 form a series of concentric closed-loop elements around the drain region 272. The high-k field relief dielectric structure 222 abuts the drain region 272. The other elements of the LDMOS transistor 201 include the gate electrode 258, the sidewall 215, the source region 271, the back gate region 277, and the STI dielectric region 239.

While various embodiments of the present disclosure have been described above, it should be understood that they have been presented by way of example only and not limitation. As such, although foregoing examples are described to use various resist layers (e.g., photoresist or photomask layers) to perform various process steps (e.g., implant steps or etch steps), the present disclosure is not limited thereto. For example, one or more hard masks (including one or more layers) may be patterned to define various regions for subsequent process steps to be applied (e.g., regions for receiving dopant atoms, regions to block etchants). Moreover, the resist layers may include multi-level resists instead of a single-level resist in some examples. Numerous changes to the disclosed embodiments can be made in accordance with the disclosure herein without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A microelectronic device, comprising:
a semiconductor material of a substrate, the semiconductor material including a body region having a first conductivity type and a drain drift region having a second conductivity type;
a gate dielectric layer on the substrate, the gate dielectric layer extending part way over the body region and part way over the drain drift region, wherein the gate dielectric layer extends over an intersection between the body region and the drain drift region;
a field relief trench in the drain drift region, the field relief trench having a recessed local oxidation of silicon profile;
a high-k field relief dielectric structure in the field relief trench and over the drain drift region, the high-k field relief dielectric structure including a high-k dielectric material, the high-k field relief dielectric structure extending from the gate dielectric layer toward a drain region and having a thickness greater than the gate dielectric layer;
a gate electrode over the gate dielectric layer;
a source region having the second conductivity type contacting the body region, the source region having an average dopant density greater than the average dopant density of the body region; and
a drain region having the second conductivity type contacting the drain drift region, the drain region having an average dopant density greater than an average dopant density of the drain drift region.

2. The microelectronic device of claim 1, where a dielectric liner is on the drain drift region in the field relief trench, the dielectric liner being located between the drain drift region and the high-k field relief dielectric structure.

3. The microelectronic device of claim 2, wherein the dielectric liner is silicon dioxide.

4. The microelectronic device of claim 1, wherein a field oxide surrounds the source region, the body region, the drain drift region, and the drain region.

5. The microelectronic device of claim 4, wherein the field oxide is Shallow Trench Isolation (STI).

6. The microelectronic device of claim 1, wherein a high-k field relief dielectric layer is selected from a group consisting of silicon nitride, silicon oxynitride, aluminum oxide, hafnium dioxide, hafnium silicate, zirconium silicate, and zirconium dioxide.

7. The microelectronic device of claim 1, wherein the first conductivity type is p-type and the second conductivity type is n-type.

8. The microelectronic device of claim 1, wherein the gate electrode has a closed-loop configuration.

9. The microelectronic device of claim 1, wherein the microelectronic device is selected from the group consisting of a laterally diffused metal oxide semiconductor (LDMOS) transistor, a drain extended metal oxide semiconductor (DENMOS) transistor, a gated bipolar semiconductor device, a gated unipolar semiconductor device, an insulated gate bipolar transistor (IGBT), a metal oxide semiconductor (MOS)-triggered SCR, a MOS-controlled thyristor, and a gated diode.

10. The microelectronic device of claim 1, wherein the high-k field relief dielectric structure has a dielectric constant of greater than 5.

11. A method of forming a microelectronic device, comprising:
forming a body region and a drain drift region in a semiconductor material of a substrate, the body region having a first conductivity type and the drain drift region having a second conductivity type;
forming a LOCOS layer in the drain drift region;
forming a field relief trench in the drain drift region, the field relief trench being formed by removing the LOCOS layer and having a recessed local oxidation of silicon profile;
forming a high-k field relief dielectric structure over the drain drift region in the field relief trench, the high-k field relief dielectric structure consisting of a high-k field relief dielectric material, the high-k field relief dielectric structure being greater in thickness than a gate dielectric layer;
forming a gate dielectric layer on the substrate, the gate dielectric layer extending part way over the body region and part way over the drain drift region, wherein the gate dielectric layer extends over an intersection between the body region and the drain drift region;
forming a gate electrode over the gate dielectric layer;
forming a source region having the second conductivity type contacting the body region, the source region having an average dopant density greater than the average dopant density of the body region; and
forming a drain region having the second conductivity type contacting the drain drift region, the drain region having an average dopant density greater than an average dopant density of the drain drift region.

12. The method of claim 11, wherein a dielectric liner is formed on the drain drift region in the field relief trench, the dielectric liner being between the drain drift region and the high-k field relief dielectric structure.

13. The method of claim 12, wherein the dielectric liner is formed using an ISSG process.

14. The method of claim 11, wherein a field relief dielectric cap layer is formed on the high-k field relief dielectric structure.

15. The method of claim 11, wherein a field oxide is formed which surrounds the source region, the body region, the drain drift region, and the drain region.

16. The method of claim 15, wherein the field oxide is formed using STI.

17. The method of claim 15, wherein a field relief dielectric cap layer is removed after the field oxide is formed.

18. The method of claim 11, wherein a high-k field relief dielectric layer is selected from a group consisting of silicon nitride, silicon oxynitride, aluminum oxide, hafnium dioxide, hafnium silicate, zirconium silicate, and zirconium dioxide.

19. The method of claim 11, wherein the high-k field relief dielectric structure has a dielectric constant of greater than 5.
